(19) United States
(12) Patent Application Publication
(10) Pub. No.: US 2003/0219923 A1
(43) Pub. Date: Nov. 27, 2003

(54) Method and system for fabricating electronics

(76) Inventors: Arokia Nathan, Waterloo (CA); Frauke Greve, Bremen (DE)

Correspondence Address: PEARNE & GORDON LLP, 526 SUPERIOR AVENUE EAST, SUITE 1200, CLEVELAND, OH, 44114-1484, US

(21) Appl. No.: 10/378,445

(22) Filed: Mar. 3, 2003

(30) Foreign Application Priority Data
Mar. 1, 2002 (CA) 2,374,338

(51) Int. Cl. H01L 51/40

(52) U.S. Cl. 438/99

(57) ABSTRACT

A method and system for fabricating large area, mechanically flexible electronics is disclosed. A fabrication system includes a drawing device for applying solution on a substrate during drawing of the pattern of a circuit, and a controller for adjusting the application of the solution to the substrate. The drawing device may include a reservoir for supplying solution, such as polymer solution, to a drawing element, such as a pen, the tip of a marker. The movement and the speed of the drawing device and a table on which the substrate is placed is determined based on the image of the pattern.

### FIELD OF THE INVENTION

The present invention relates to a fabrication technique, more specifically to a method and system for fabricating electronics.

### BACKGROUND OF THE INVENTION

The development of and advances in conducting polymers have allowed these material to find application in a wide range of electronic devices including organic light emitting diodes (OLEDs) and organic thin film transistors (OTFTs). There are however remaining issues regarding the fabrication procedures used for these devices.

OLEDs can incorporate either conductive polymers or small molecule materials within the light producing component. Fabrication of OLEDs, when using small molecule materials, often uses mask techniques. In such techniques, masks are used to define the electronic devices, i.e. the desired pattern is produced using the masks.

Producing devices that incorporate conductive polymers is however more complicated. Spin-coating of a conductive polymer solution will provide a thin homogeneous layer of material. However, as this layer covers the entire substrate, it will require patterning. Standard patterning techniques that implement photolithographic patterning are difficult for the case of conductive polymers. For example, the etching solutions and solvents of wet etching steps may disturb layers other than that for which the procedure is intended. The situation is further complicated in the production of color OLEDs. The fabrication of such devices will likely require deposition and patterning steps for each cooler, i.e. each conductive polymer associated with a different color.

In an effort to overcome the need for patterning steps some research groups have developed inkjet printing techniques for the deposition of the polymer solution. Other groups are using screen-printing to provide full-color displays. In both of these techniques, the deposition of material occurs in specific locations eliminating the need for patterning steps.

Inkjet printing is a precise and convenient technology. Inkjet printing offers good resolution and its set up is easy. Further, unlike spin-coating, there is little waste of polymer material. However, there are issues such as clogging of the nozzles, compatibility of the printer hardware to many solvents and connectivity of discrete dots created during such printing. With respect to the latter point the polymer solution cab be modified to lower its surface tension such that the discrete dots of the printed pattern are connected to each other to form a continuous layer. At least one parameter from the group including polymer solution chemistry, printing surfaces and hardware, must be modified for use of inkjet printing as a fabrication tool.

There is, therefore, a need for a new deposition technique that is applicable to a wide variety of electronics and for fabricating large area electronics. This technique should provide a continuous deposition that does not require subsequent patterning.

### SUMMARY OF THE INVENTION

It is an object of the invention to provide a novel method and system that obviates or mitigates at least one of the disadvantages of existing systems.

In accordance with an aspect of the present invention, there is provided a system for fabricating electronic circuits, which includes: a table for supporting a substrate in a horizontal direction; a drawing device for supplying solution to the substrate to draw a pattern of a circuit on the substrate; and a controller for operating the drawing device so as to fabricate a continuous layer in response to an image of the pattern.

In accordance with a further aspect of the present invention, there is provided a method of fabricating electronic circuits using a fabrication system, which has a drawing device. The method includes the steps of: reading an image of a pattern; supplying solution to a substrate to draw the pattern on the substrate with the drawing device; and controlling the relative position between the substance and the drawing device in response to an image of the pattern.

In accordance with a further aspect of the present invention, there is provided a method of fabricating large area electronics. The method includes steps of: using a plotter for patterning a fist conductive polymer on a thin layer of anode; on top of the pattern, spin-coating a second polymer; and evaporating a cathode.

Other aspects and features of the present invention will be readily apparent to those skilled in the art from a review of the following detailed description of preferred embodiments in conjunction with the accompanying drawings.

### BRIEF DESCRIPTION OF THE DRAWINGS

The invention will be further understood from the following description with reference to the drawings in which:

FIG. 1 is a schematic diagram showing a fabrication system in accordance with an embodiment of the present invention;

FIG. 2 is a schematic diagram showing one example of the fabrication system shown in FIG. 1;

FIG. 3 is a schematic cross-section view showing one example of design steps; and

FIG. 4 is a graph showing one example of device characteristics for a device fabricated using the fabrication system of FIG. 2.

### DETAILED DESCRIPTION OF THE PREFERRED EMBODIMENTS

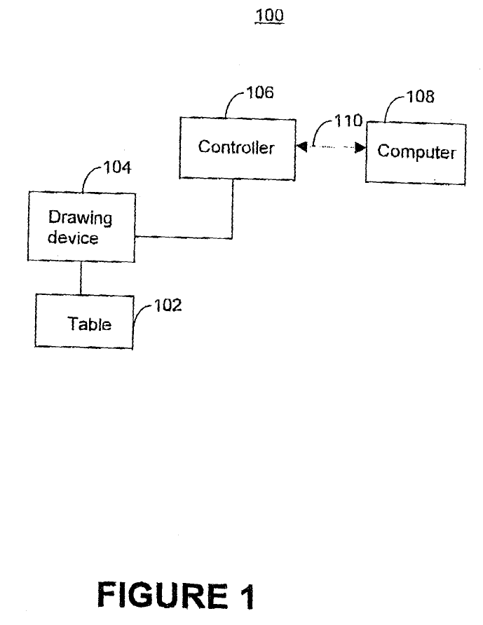

FIG. 1 shows a fabrication system 100 in accordance with an embodiment of the present invention. The fabrication system 100 includes a table 102, a drawing device 104 and a controller 106. Substrates for the formation of circuits are placed on the table 102. The drawing device 104 applies solution to the substrate during drawing of the pattern of the circuit on the substrate. The drawing device 104 may include a fiber pen, a polymeric marker, a magic marker or a fountain pen or the like. The drawing device 104 is movable in multiple directions while the table 102 is movable in at least one direction.

The controller 106 is connected to an external device, i.e. a computer 108, through a communication network 110. The controller 106 operates the system 100 based on the image of the pattern read from the computer 108. In response to the pattern, the controller 106 determines the movement of the table 102 and the drawing device 104. The controller 106 further controls the speed of the movement. The controller 106 also controls the supply of the solution from the drawing device 104 to the substrate, which defines the thickness of the layer drawn on the substrate. The above apparatus is relatively simple and is able to handle a wide rage of materials including conductive polymer solutions. It may be implemented to apply materials for use in electronic structures including resistors, capacitors, inductors, light-emitting and non-light emitting diodes and transistors. Further, such structures may be formed on a variety of substrates including paper, plastic, polyester and glass.

The parameters used to operate the fabrication system 100 may be changed in the controller 106 or in the computer 108. Users may operate the controller 106 either directly or through the computer 108.

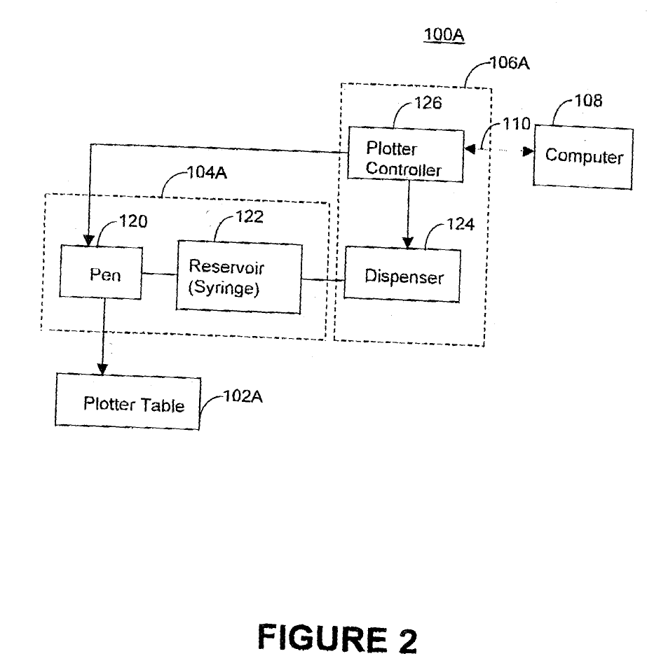

FIG. 2 presents an example of the fabrication system 100 shown in FIG. 1. The fabrication system 100A of FIG. 2 includes the drawing device 104A and the controller 106A. The drawing device 104A includes a plotter pen (fiber) 102 and a reservoir 122. The reservoir 122 may be a syringe 122, which is compatible with a wide variety of solvents. For example, the reservoir 122 provides polymer solution to the fiber. Substrates are placed flat on the plotter table 102A and are moved horizontally during the operation of the system 100A.

The controller 106A includes a dispenser 124 and a plotter controller 126. The plotter controller 126 determines the position and the speed of the table 102A and the drawing device 104A The plotter controller 126 additionally controls the dispenser 124, to which the reservoir 122 is connected. The dispenser 124 provides either a pressure or a vacuum, to adjust the application of the polymer solution to the substrate. The magnitude of the pressure and the vacuum are adjustable.

The controllers 106 and 106A have functionality for determining the rate of the fabrication process. For example, decreasing the speed at which the drawing device 104 and 104A moves across the substrate improves the homogeneity of the drawn/plotted layers.

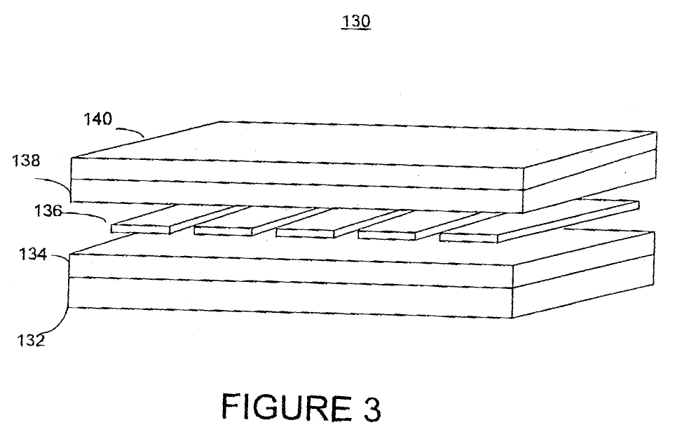

FIG. 3 shows one example of design steps in accordance with an embodiment of the present invention. A circuit design 130 shown in FIG. 3 includes a substrate 132 covered with a thin layer of poly(3,4-ethylenedioxythiophene)/poly (styrenesulfonate) (PEDOT/PSS) 134, a conductive polymer layer of PEDOT/PSS 136, an emitting polymer layer 138 and a cathode layer 140. The PEDOT is a hole injection material and is a hole transport material.

For example, the substrate 132 is a plastic layer, such as PET (100 μm, Delta Technologies, USA). The material of substrate 132 may be glass or any other material. The substrate serves as an anode.

For example, Bayton is used as the layer 136. Bayton is an aqueous dispersion of the intrinsically conductive polymer PEDOT doped with PSS. When inserting a very thin layer (about 50-100 nm) of Bayton between the transparent anode and the emitting polymer layer 138, the efficiency and lifetime of the device 130 can be improved and the device operating voltage can be decreased.

The emitting layer 138 is a MEH-PPV layer. Poly(p-phenylenevinylene) PPV is a conjugated polymer with an energy gap between π and π* states of about 2.5 eV. It produces luminescence in a band below this energy (Stokes Shift). MEH-PPV poly (2-methoxy, 5-(2′-ethyl-hexoxy)-p-phenylenevinylene) is a semiconductor with an energy gap of 2.1 eV (high occupied molecular orbital: HOMO at 5.3 eV, lowest unoccupied molecular orbital: LUMO at 3.0 eV). It is orange-red emitting. It is soluble in organic solvents such as halogenated hydrocarbons, chloroform and aromatic hydrocarbons such as toluene. A thin layer of MEH-PPV dissolved in chloroform is spin-coated onto the patterned PEDOT layer 136.

The material of the cathode layer 140 may be aluminum calcium or lithium. The cathode material is evaporated.

Any materials, such as MEH-PPV dissolved in chloroform (e.g. the layer 138), are patterned with the fabrication system 100. The layer 136 is also patterned with the fabrication system 100, using polymer solution.

An example of the process for patterning conductive polymer PEDOT on the anode is described. A PET substrate covered with a thin layer of PEDOT/PSS is used as the anode (132 and 134 of FIG. 3). The fabrication system 100A of FIG. 2 is used to pattern the conductive polymer PEDOT on the anode to obtain the desired image. A layer of MEH-PPV is then spin-coated on the deposited/drawn material. An aluminum cathode is then evaporated on the MEH-PPV layer.

When PEDOT/PSS is used without any modification, it sticks inside the syringe since the adhesion between the syringe and the polymer is high. A reduction of the adhesion can be achieved when a surfactant is mixed with the PEDOT solution. For example, isopropanol is mixed with PEDOT at a ratio (10:2). This reduces the adhesion.

In the current example, the pen plotter 120 and a part of the plotter controller 126 are formed by Hewlett-Packard 7475A plotter. A syringe is used as the reservoir 122, which replaces the ink reservoir of HP 7475A. Further, the dispenser 124 is attached to the syringe 122 and an appropriate control to the dispenser 124 is added. The syringe is filled with the polymer solution. In this example, the syringe is filled with ca. 2 ml (0.45 μm-filtered) PEDOT solution.

Before the operation, the fiber of the plotter pen 120 and the path (including a syringe tip) between the fiber of the plotter pen 120 and the syringe 122 are cleaned ultrasonically in de-ionized-water to remove all PEDOT/PSS particles. This step washes out residuals in the plotter pen 120 and the path between the plotter pen 120 and the syringe 122, and prevents possible clogging. After cleaning, the fiber is returned to the plotter pen 120. The plotter pen 120 is attached to the syringe 122 through the syringe tip.

The dispenser 124 is electrically connected to the “pen-down/up” button (e.g. a part of the controller 126 shown in FIG. 2). When the “pen-down” button is pressed and the magnitude of the pressure is appropriately adjusted, the dispenser 124 provides an appropriate pressure that pushes the polymer solution of the syringe 122 into the fiber, which in turn places the solution on the substrate. When the “pen-up” button is pressed and the magnitude of the vacuum is appropriately adjusted, the dispenser 124 provides the appropriate vacuum such that the polymer solution is retained in the syringe 122 and does not flow back into the dispenser 124. The thickness of the deposited layer is determined by the magnitude of the pressure supplied by the dispenser 124. The pressure and the vacuum are parameters that depend on the viscosity of the polymers. The parameters are adjusted through the controller 106A.

The image of the pattern is drawn in the computer 108 and sent to the controller 106A.

A transparency is placed on the plotter table 120A. The image of the circuit pattern is plotted on the transparency. Then, a substrate (e.g. ca. 2″×2″) is taped on the already drawn image. The image is then plotted on the substrate.

During the operation, the “pen-down” button and “pen-up” button are operated, As described above, the “pen-down” button and “pen-up” button controls the dispenser 124 so as to apply a pressure or a vacuum to the syringe 122.

In this embodiment, for plotting PEDOT/PSS, the optimal pressure is around 0.6-0.8 bar for pushing the polymer into the fiber before beginning the process. Once the polymer reached the fiber and the first pattern is plotted, the pressure is set to zero for normal operation.

The substrate is removed from the transparency and put into an oven. In one embodiment, the oven is maintained at 60° C. for a time of 24 hours to remove the solvent.

The next step is the fabrication of the emitting polymer. After drying the PEDOT/PSS layer (e.g. 136 of FIG. 3), MEH-PPV is spin-coated on the top of the polymer layer. MEH-PPV may be plotted using an appropriate polymer solution.

The next step is the fabrication of the aluminum cathode. The aluminum cathode is evaporated in a Varian e-beam evaporator (e.g. at ca. 5×10⁻⁵ Torr, 100 nm e-beam current and 2 minutes evaporation time).

Further example is described. The fabrication system 100A, which was used for patterning conductive polymer PEDOT, was used to fabricate devices as described below.

In another example a resistor was fabricated. The resistor pattern was plotted on a on a glass substrate with the plotter pen 120 of HP 7475A. The thickness of the layer was defined by the applied pressure of the dispenser 124. The resistor was dried in an oven at 60° C. for 1 hour. Aluminum electrodes were evaporated through a shadow mask on the layers to improve ohmic contact.

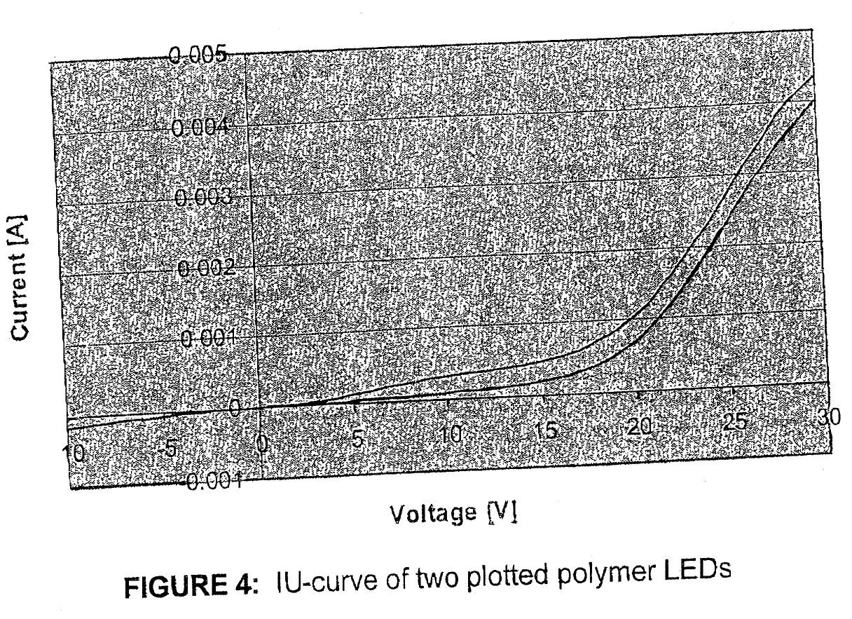

In another example a PLED was fabricated using plotting techniques. The pattern was plotted onto the PET substrate covered with a thin layer of PEDOT/PSS. Spin-coating of MEH-PPV was then carried out. Aluminum evaporation was then carried out. Two devices were fabricated according to the above method. FIG. 4 shows the characteristic curves of these devices. The threshold voltages of the devices are around 15 Volts and 18 Volts, respectively.

According to the embodiment of the present invention, mechanically flexible circuits, in which substrates are flexible, are fabricated. The fabrication system 100 handles a wide variety of substrates, such as glass, plastic, paper and polyester. As the substrate is laying flat on the table 120 and is moved horizontally, the substitute is not bended on the table 102.

The fabrication system 100 allows the patterns on the substrates to be continuous and homogeneous. Circuits with large area are fabricated with the fabrication system 100. Further, patterns of the different layers in the electronic device are directly written/plotted on the substrate.

Further, the fabrication technique in accordance with the embodiment of the present invention is relatively simple and is applicable to a variety of application areas including the plotting/drawing of electronics on grocery packaging and other household items, personal effects (e.g. clothing, etc.), electronic labeling, electronic signage in roads and buildings, etc.

The fabrication technique in accordance with the embodiment of the present invention is extended to create a new generation of hobby electronics using polymeric markers/fountain pens, where circuits (including their synthesis) can be simply plotted or drawn.

The fabrication technique in accordance with the embodiment of the present invention provides the capacity to plot/draw patterns of biological material thus addressing a new and promising technique for bioMEMS.

While particular embodiments of the present invention have been shown and described, changes and modifications may be made to such embodiments without departing from the true scope of the invention.

What is claimed is:

1. A system for fabricating electronic circuits, the system comprising:
a table for supporting a substrate in a horizontal direction;
a drawing device for applying solution to the substrate to draw a pattern of a circuit on the substrate; and
a controller for operating the drawing device so as to fabricate a continuous layer in response to an image of the pattern.

2. The system of claim 1, wherein the solution is a conductive polymer solution.

3. The system of claim 1, wherein the controller continuously determines the position between the table and the drawing device based on the image.

4. The system of claim 3, wherein controller determines the relative speed between the table and the drawing device based on the image.

5. The system of claim 4, wherein controller adjusts the supply of the solution to the substrate based on the image.

6. The system of claim 1, wherein the drawing device includes a drawing element for drawing the pattern on the substrate and a reservoir for supplying the solution to the drawing element in response to the instruction of the controller.

7. The system of claim 6, wherein the controller controls the supply of the solution to the substrate, which defines the thickness of a layer drawn on the substrate.

8. The system of claim 1, wherein the drawing device supplies the solution to draw the pattern of an organic light emitting device.

9. The system of claim 1, wherein the drawing device supplies the solution to draw the pattern of a transistor.

10. The system of claim 1, further comprising an external device for generating the image of the pattern and for sending the image to the controller.

11. The system of claim 6, wherein the drawing element is selected from the group consisting of a fiber pen, a magic marker, a polymeric marker and a fountain pen.

12. A method of fabricating electronic circuits using a fabrication system, the fabrication system including a drawing, device the method comprising steps of:
reading an image of a pattern;
applying solution to a substrate to draw the pattern on the substrate with the drawing device; and
controlling the relative position between the substance and the drawing device based on an image of the pattern.

13. A method of claim 12, further comprising the step of controlling the relative speed between the substrate and the drawing device based on the image of the pattern.

14. A method of claim 12, further comprising the step of adjusting the supply of the solution to the substrate based on the image of the pattern.

15. A method of fabricating large area electronics, the method comprising steps of:
using a plotter for patterning a first conductive polymer on a thin layer of anode;
on top of the pattern, spin-coating a second polymer; and
evaporating a cathode.

16. A method according to claim 15, wherein the anode is PEDOT/PSS.

17. A method according to claim 15, wherein the first conductive polymer is PEDOT.

18. A method according to claim 15, wherein the second conductive polymer is MEH-PPV.

19. A method according to claim 15, wherein the cathode is aluminum.

20. A method according to claim 15, wherein the anode includes a substrate selected from the group consisting of paper, plastic, polyester and glass.
